(19) United States
(12) Patent Application Publication
(10) Pub. No.: US 2008/0006846 A1
(43) Pub. Date: Jan. 10, 2008

(54) III-V NITRIDE SEMICONDUCTOR DEVICE AND METHOD OF FORMING ELECTRODE

(75) Inventors: Nariaki Ikeda, Tokyo (JP); Seikoh Yoshida, Tokyo (JP)

Correspondence Address: OBLON, SPIVAK, MCCLELLAND MAIER & NEUSTADT, P.C., 1940 DUKE STREET, ALEXANDRIA, VA, 22314, US

(73) Assignee: The Furukawa Electric Co, Ltd., Tokyo (JP)

(21) Appl. No.: 11/839,895

(22) Filed: Aug. 16, 2007

Related U.S. Application Data
(63) Continuation of application No. PCT/JP06/10484, filed on May 25, 2006.

(30) Foreign Application Priority Data
Jun. 3, 2005 (JP) 2005-163858

(51) Int. Cl. H01L 31/00

(52) U.S. Cl. 257/192

(57) ABSTRACT

A III-V nitride semiconductor device includes an n-type layer of a III-V nitride semiconductor and an electrode formed on a surface of the n-type layer. A material of the electrode includes at least titanium, aluminum, and silicon.

### CROSS-REFERENCE TO RELATED APPLICATIONS

This application is a continuation of PCT/JP2006/310484 filed on May 25, 2006, the entire content of which are incorporated herein by reference.

### BACKGROUND OF THE INVENTION

1. Field of the Invention

The present invention generally relates to a III-V nitride semiconductor device that includes a low contact-resistant electrode formed on an n-type layer of the III-V nitride semiconductor and a method of forming the electrode.

2. Description of the Related Art

Semiconductors including a nitride-based III-V group compound, such as GaN, InGaN, AlGaN, and AlInGaN, are direct bandgap semiconductors having large energies with reliable performances in a high temperature. Particularly, electronic devices or optical devices including GaN, such as a light emitting element, a light receiving element, a field effect transistor (FET), or a high electron mobility transistor (HEMT), have been studied and developed recently.

In a technique for fabricating an FET including GaN, a GaN buffer layer is formed on a semi-insulating substrate, such as a sapphire substrate, by employing the metal organic vapor deposition (MOCVD) method or the gas source molecular beam epitaxy (GSMBE) method. Semiconductor layers including GaN-based compounds with a predetermined composition are sequentially grown on the GaN buffer layer. As a result, an n-type layer having a predetermined layer structure in which a top surface layer functions as an active layer is fabricated. On the active layer, a source electrode, a drain electrode, and a gate electrode are formed. The gate electrode is positioned between the source electrode and the drain electrode.

In a typical technique for forming the above electrodes, a material for the electrodes is directly deposited on a surface of the n-type layer with a predetermined thickness by, for example, a vapor deposition. Thereafter, the electrodes formed on the n-type layer are annealed entirely. A structure of such electrodes includes a Ti layer and an Al layer. The electrodes formed on the n-type layer are required to show a high adhesiveness and a low contact resistance to the n-type layer.

Patent document 1: Japanese Patent Laid-open No. 2004-55840

Patent document 2: Japanese Patent Laid-open No. H7-221103

### DISCLOSURE OF INVENTION

### Problem to Be Solved by the Invention

Most of the electrodes formed on the n-type layer of the III-V nitride semiconductor, more particularly a GaN-based semiconductor, have a layer structure including Ti and Al deposited as materials of the electrodes by using a vacuum evaporation method or the like, and are annealed to form an ohmic contact. The higher temperature the electrodes are annealed at, the more strongly the electrodes adhesives to the semiconductor layer, because Ti layer formed on the surface of the n-type layer of the III-V nitride semiconductor well reacts with the nitride-based III-V group compound. However, when Al, which has a melting point of near 660° C., is used as a material of the electrodes, the annealed electrodes show a poor surface morphology and a contact resistance not low enough.

### SUMMARY OF THE INVENTION

It is an object of the present invention to at least partially solve the problems in the conventional technology.

A III-V nitride semiconductor device according to one aspect of the present invention includes an n-type layer of a III-V nitride semiconductor; and an electrode formed on a surface of the n-type layer. A material of the electrode includes at least titanium, aluminum, and silicon.

A method according to another aspect of the present invention is for forming an electrode on a III-V nitride semiconductor, which includes a layer formed with at least titanium, aluminum, and silicon. The method includes forming a first layer including at least titanium on a surface of an n-type layer of the III-V nitride semiconductor; and forming a second layer including aluminum and silicon on the first layer.

A method according to still another aspect of the present invention is for forming an electrode on a III-V nitride semiconductor, which includes a layer formed with at least titanium, aluminum, and silicon. The method includes forming a titanium layer on a surface of an n-type layer of the III-V nitride semiconductor; forming a silicon layer on the titanium layer; forming an aluminum layer on the silicon layer; and performing an annealing of the electrode.

The above and other objects, features, advantages and technical and industrial significance of this invention will be better understood by reading the following detailed description of presently preferred embodiments of the invention, when considered in connection with the accompanying drawings.

### BRIEF DESCRIPTION OF THE DRAWINGS

FIG. 1 is a cross-sectional view of a GaN-based semiconductor FET according to a first embodiment of the present invention;

FIG. 2 is a chart for comparing semiconductor devices having different structures of electrodes in contact resistance;

FIG. 3 is a cross-sectional view of a GaN-based semiconductor FET according to a second embodiment of the present invention; and

FIG. 4 is a cross-sectional view of a GaN-based semiconductor FET according to a third embodiment of the present invention.

### DETAILED DESCRIPTION OF THE PREFERRED EMBODIMENTS

Exemplary embodiments of the present invention will be described in detail below with reference to the accompanying drawings. The present invention is not limited to these exemplary embodiments.

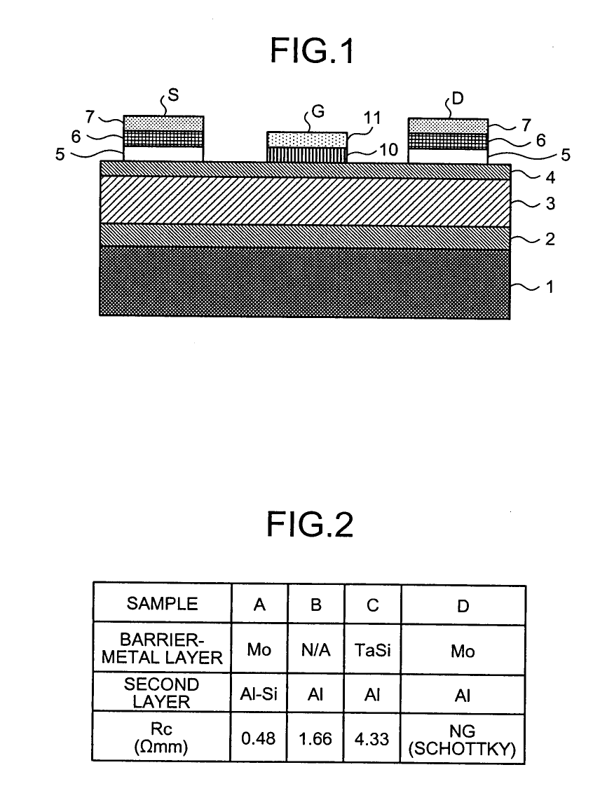

FIG. 1 is a cross-sectional view of a GaN-based semiconductor FET as an example of the III-V nitride semiconductor device according to a first embodiment of the present invention. The GaN-based semiconductor FET includes a silicon (111) substrate 1 on which a buffer layer including, for example, GaN, an undoped GaN layer functioning as a channel layer 3 of the FET, and an undoped AlGaN layer functioning as an electron-supplying layer 4 are sequentially formed. On the undoped AlGaN layer, a source electrode S, a gate electrode G, and a drain electrode D are formed.

Because the undoped GaN layer (the channel layer 3), which defines a length of a channel, and the undoped AlGaN layer (the electron-supplying layer 4) creates a heterojunction, a two-dimensional electron gas is generated on an interface of a junction area. Because the two-dimensional electron gas functions as a carrier, the channel layer 3 shows a conductive property. Each of the source electrode S and the drain electrode D includes a Ti layer 5, an Al—Si alloy layer 6 including a disordered phase of Al and Si, and a Mo layer 7, those sequentially deposited from the side closer to the surface of the electron-supplying layer 4. The gate electrode G includes a Ni layer 10 and a Au layer 11, sequentially deposited.

FIG. 2 is a chart for comparing semiconductor devices having different structures of the source electrode S and the drain electrode D in contact resistance Rc. A sample A indicates a semiconductor device including the source electrode S and the drain electrode D according to the first embodiment. Samples B to D indicate semiconductor devices including conventional source electrodes and drain electrodes. Each of the electrodes in the samples includes a Ti layer as a first layer formed on the electron-supplying layer 4 and a layer including a disordered phase of Al and Si or an Al layer as a second layer formed on the first layer. A barrier-metal layer is a layer formed on the second layer.

As shown in FIG. 2, The sample A including the disordered phase of Si and Al as the second layer, has a much lower contact resistance Rc than those of the samples B to D including the Al layer as the second layer according to the conventional techniques. It means that a GaN-based semiconductor FET with a much lower On-resistance at the operation can be realized using the sample A.

The substrate 1 made of Si (111) is arranged in an MOCVC device. After a chamber of the MOCVD is pumped to be at 1×10⁻⁶ hPa or lower by a turbo pump, the substrate 1 is heated at 1100° C. at 100 hPa. When the temperature becomes stable, the substrate 1 starts spinning at 900 rpm, and trimethylaluminum (TMA) with a feed rate of 100 cm³/min and ammonia with a feed rate of 12 L/min, which are used as materials, are injected to a surface of the substrate 1 to grow a GaN buffer layer 2. A growth time of the GaN buffer layer 2 is 4 minutes, and a thickness of the GaN buffer layer 2 is about 50 nanometers.

Subsequently, trimethylgallium (TMG) with a feed rate of 100 cm³/min and ammonia with a feed rate of 12 L/min are injected to a surface of the buffer layer 2 to grow the channel layer 3 formed with a GaN layer. A growth time of the channel layer 3 is 1000 seconds, and a thickness of the channel layer 3 is about 800 nanometers. Further subsequently, trimethylaluminum (TMA) with a feed rate of 50 cm³/min, trimethylgallium (TMG) a feed rate of 100 cm³/min, and ammonia a feed rate of 12 L/min are injected to grow the electron-supplying layer 4 including Al_{0.25}Ga_{0.75}N. A growth time of the electron-supplying layer 4 is 40 seconds, and a thickness of the electron-supplying layer 4 is 20 nanometers. As a result of the above process, the structure of the semiconductor device shown in FIG. 1 (except the electrodes) is formed.

A SiO₂ film is formed on the electron-supplying layer 4 by using, for example, the plasma chemical vapor deposition (CVD) method. A thickness of the SiO₂ film is about 300 nanometers. After patterning the SiO₂ film so that an area where the gate electrode G is to be formed is masked and areas where the source electrode S and the drain electrode G are to be formed are opened, the source electrode S and the drain electrode D are formed by sequentially depositing Ti, an Al—Si alloy film, and Mo on the opened area of the surface of the electron-supplying layer 4. After the above layers are deposited, the electrodes are annealed at 900° C. for one minute. A thickness of the Ti layer 5 is 0.25 micrometer. A thickness of the Al—Si alloy layer 6 is 0.10 micrometer, and an Al:Si composition ratio is 0.88:0.12. Next, after the areas where the source electrode S and the drain electrode G are formed are masked with the SiO₂ film and the area where the gate electrode G is to be formed is opened, the gate electrode G is formed by sequentially depositing Ni and Au. As a result, the FET shown in FIG. 1 is fabricated. The contact resistance of the source electrode S and the drain electrode D of the FET fabricated in the above process is 0.5 Ωmm.

According to an Auger analysis of a cross-sectional surface of the annealed electrodes, Al is diffused to the Ti layer, which forms a TiAl layer of a thickness of 0.025 micrometer, which has a Ti:Al composition ratio of 25:60. Similarly, Mo is diffused to the AlSi layer on the TiAl layer, which forms a 0.1-micrometer-thick disordered phase, which has an Al:Si:Mo composition ratio of about 57:7:10. It is found from the analysis that, although some elements included in the electrodes are diffused, the surface morphology of the annealed electrodes are not degraded comparing with those of the electrodes before the annealing process and no trouble is caused about wire bonding.

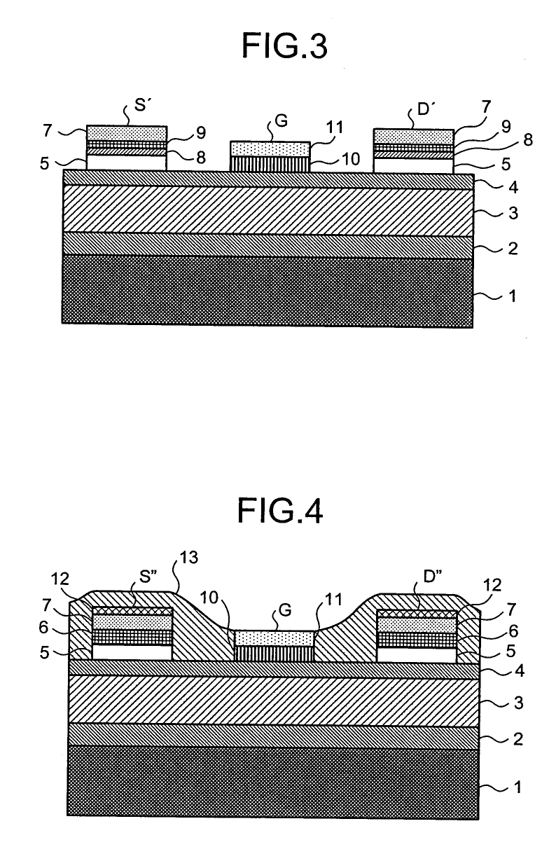

FIG. 3 is a cross-sectional view of a GaN-based semiconductor FET as an example of a III-V nitride semiconductor device according to a second embodiment of the present invention. The semiconductor part is fabricated in a manner similar to that in the first embodiment. In the process of forming the electrodes, Ti layer 5 of a thickness of 0.025 micrometer, a Si layer 8 of a thickness of 0.010 micrometer, and an Al layer 9 of a thickness of 0.090 micrometer are sequentially deposited on areas where a source electrode S′ and a drain electrode D′ is to be formed. Subsequently, the Mo layer 7 is formed on the Al layer 9. The gate electrode G is formed by sequentially depositing the Ni layer 10 and the Au layer 11 on the area for the gate electrode. Subsequently, the electrodes are annealed at 900° C. for one minute. In the annealed source electrode S′ and the annealed drain electrode D′, a disordered phase of Si and Al is formed, and a contact resistance is 0.5 Ωmm.

As a result of the formation of the disordered phase of Si and Al in the above process, parts of Si and Al can be remained not included in the disordered phase, forming layers positioned upper and lower parts of the disordered phase. In this case, the formed source electrode S′ and the formed drain electrode D′ include the Ti layer 5 on which the Si layer, the layer including the disordered phase of Si and Al, and the Al layer are sequentially deposited.

FIG. 4 is a cross-sectional view of a GaN-based semiconductor FET as an example of a III-V nitride semiconductor device according to a third embodiment of the present invention. As shown in FIG. 4, the GaN-based semiconductor FET according to the third embodiment includes, based on a structure of the GaN-based semiconductor FET according to the first embodiment, a source electrode S″ and the drain electrode D″ obtained by forming a Ti layer 12 on a top surface layer of each of the source electrode S and the drain electrode D. In addition, an insulating protective film 13 including SiOₓ or SiNₓ is formed over the source electrode S″ and the drain electrode D″.

By forming the Ti layer 12 functioning as an adhesive layer as the top surface layer of each of the source electrode S and the drain electrode D, which is placed a boundary surface between the electrodes and the insulating protective film 13, an adhesiveness of the insulating protective film 13 to the electrodes is more improved than that in the case the insulating protective film 13 is directly formed on the Mo layer 7. The Mo layer 7 can be replaced with a layer including Nb, Ta W, Re, Os, Ni, Pt or IR. Similarly, if the Ti layer is formed on the above replacing layer, the adhesiveness of the insulating protective film 13 to the electrodes is improved. It is also allowable to replace the Mo layer 7 with the Ti layer and form the insulating protective film 13 on the replacing Ti layer.

The GaN-based semiconductor FET according to the third embodiment is fabricated in the similar process for fabricating the GaN-based semiconductor FET according to the first embodiment. Unlike the electrode forming process in the first embodiment, the source electrode S″ and the drain electrode D″ are formed by performing the annealing process after the Mo layer 7 and the Ti adhesive layer are deposited. After the gate electrode G is formed, the insulating protective film 13 is deposited. Although the annealing process can be performed before the Ti adhesive layer is deposited and after the Mo layer 7 is deposited, the annealing process is preferably performed after the Ti layer is deposited in the light of simplifying the fabricating process.

As described above, according to one aspect of the present invention, it is possible to obtain an effect of forming the low contact-resistant electrodes having a high adhesiveness to the surface of the semiconductor by using at least Ti, Al, and Si as materials of the electrodes.

Although the invention has been described with respect to a specific embodiment for a complete and clear disclosure, the appended claims are not to be thus limited but are to be construed as embodying all modifications and alternative constructions that may occur to one skilled in the art that fairly fall within the basic teaching herein set forth.

What is claimed is:

1. A III-V nitride semiconductor device comprising:
an n-type layer of a III-V nitride semiconductor; and
an electrode formed on a surface of the n-type layer, wherein
a material of the electrode includes at least titanium, aluminum, and silicon.

2. The III-V nitride semiconductor device according to claim 1, wherein
the electrode includes at least a first layer and a second layer, sequentially formed on the surface of the n-type layer,
the first layer includes at least titanium, and
the second layer includes at least aluminum and silicon.

3. The III-V nitride semiconductor device according to claim 2, wherein the second layer includes a layer formed mainly with a disordered phase of aluminum and silicon.

4. The III-V nitride semiconductor device according to claim 2, wherein the second layer has a structure in which a silicon layer and an aluminum layer are deposited in order on a titanium layer.

5. The III-V nitride semiconductor device according to claim 1, wherein the electrode has a structure in which a layer formed with one element or a plurality of elements selected from a group constituting of molybdenum, niobium, tantalum, tungsten, rhenium, osmium, nickel, platinum, Iridium, and titanium is layered on a layer formed with titanium, aluminum, and silicon.

6. The III-V nitride semiconductor device according to claim 1, further comprising an insulating protective film formed on the electrode, wherein
the electrode includes a titanium layer at a boundary with the insulating protective film.

7. A method of forming an electrode on a III-V nitride semiconductor, the electrode including a layer formed with at least titanium, aluminum, and silicon, the method comprising:
forming a first layer including at least titanium on a surface of an n-type layer of the III-V nitride semiconductor; and
forming a second layer including aluminum and silicon on the first layer.

8. The method according to claim 7, further comprising forming a layer formed with one element or a plurality of elements selected from a group constituting of molybdenum, niobium, tantalum, tungsten, rhenium, osmium, nickel, platinum, Iridium, and titanium on a layer formed with titanium, aluminum, and silicon.

9. The method according to claim 7, further comprising forming a titanium layer on a top surface layer of the electrode.

10. A method of forming an electrode on a III-V nitride semiconductor, the electrode including a layer formed with at least titanium, aluminum, and silicon, the method comprising:
forming a titanium layer on a surface of an n-type layer of the III-V nitride semiconductor;
forming a silicon layer on the titanium layer;
forming an aluminum layer on the silicon layer; and
performing an annealing of the electrode.

11. The method according to claim 10, further comprising forming a layer formed with one element or a plurality of elements selected from a group constituting of molybdenum, niobium, tantalum, tungsten, rhenium, osmium, nickel, platinum, Iridium, and titanium on a layer formed with titanium, aluminum, and silicon.

12. The method according to claim 10, further comprising forming a titanium layer on a top surface layer of the electrode.
